(19) United States
(12) Patent Application Publication
(10) Pub. No.: US 2024/0274431 A1
(43) Pub. Date: Aug. 15, 2024

(54) WAFER, AND FRONT/BACK SURFACE DETERMINATION METHOD FOR WAFER

(71) Applicant: DISCO CORPORATION, Tokyo (JP)

(72) Inventor: Kazuma SEKIYA, Tokyo (JP)

(21) Appl. No.: 18/437,847

(22) Filed: Feb. 9, 2024

(30) Foreign Application Priority Data
Feb. 13, 2023 (JP) 2023-020140

(51) Int. Cl. H01L 21/02; H01L 21/68; H01L 23/544

(52) U.S. Cl. CPC H01L 21/02021; H01L 21/681; H01L 23/544; H01L 2223/54493

(57) ABSTRACT

A wafer has an outer circumferential chamfered portion, and at least three tiny flat surfaces formed along a circumferential direction of the wafer in a region of the outer circumferential chamfered portion. The flat surfaces define circular arcs between adjacent ones thereof, respectively, and at least two of the circular arcs have lengths different from each other.

### BACKGROUND OF THE INVENTION

### Field of the Invention

The present invention relates to a wafer, and a determination method for determining a front/back surface of the wafer.

### Description of the Related Art

A semiconductor wafer has crystal orientation characteristics and is subjected to a variety of processing, such as formation of devices and division into a plurality of chips, with an awareness of its crystal orientations. A notch or an orientation flat, therefore, has heretofore been formed on a conventional wafer to identify a crystal orientation. However, there is a problem in that a region in which devices can be formed is reduced by the notch or the orientation flat. A technology has hence been proposed, in which a tiny flat surface is formed on a chamfered portion of a wafer, and is used as a sign to identify a crystal orientation (see, for example, JP 2007-189093A and JP 2007-329391A).

### SUMMARY OF THE INVENTION

Depending on the wafer, two orientation flats of different lengths are formed to indicate crystal orientations. If the wafer is turned upside down, the arrangement of the orientation flats of different lengths is changed. The front surface and back surface of the wafer can thus be identified by identifying these respective two orientation flats. If two tiny flat surfaces are formed instead of the orientation flats, however, these flat surfaces are so tiny that each flat surface cannot be identified to be which one of the two flat surfaces. Such tiny surfaces therefore involve a problem that they are hardly usable as signs to identify the front surface and back surface of a wafer.

The present invention therefore has, as objects thereof, the provision of a wafer and a front/back surface determination method, which allow to determine the front or back surface of the wafer even if a tiny flat surface is formed as a mark that indicates a crystal orientation.

In accordance with a first aspect of the present invention, there is provided a wafer having an outer circumferential chamfered portion. The wafer includes at least three tiny flat surfaces formed along a circumferential direction of the wafer in a region of the outer circumferential chamfered portion. The flat surfaces define circular arcs between adjacent ones thereof, respectively, and at least two of the circular arcs have lengths different from each other.

In accordance with a second aspect of the present invention, there is provided a wafer having an outer circumferential chamfered portion. The wafer includes a flat surface inclined from a direction orthogonal to a front surface of the wafer and formed in a region of the outer circumferential chamfered portion.

In accordance with a third aspect of the present invention, there is provided a front/back surface determination method for determining a front or back surface of a wafer having an outer circumferential chamfered portion and including at least three tiny flat surfaces formed along a circumferential direction of the wafer in a region of the outer circumferential chamfered portion. The flat surfaces define circular arcs between adjacent ones thereof, respectively, and at least two of the circular arcs have lengths different from each other. The front/back surface determination method includes a detection step of irradiating a side surface of the outer circumferential chamfered portion, the side surface including the flat surfaces, with light along the circumferential direction of the wafer by a sensor having a light transmitter unit that irradiates the side surface of the outer circumferential chamfered portion with the light and a light receiver unit that receives reflected light from the side surface, thereby detecting a plurality of the flat surfaces based on the reflected light received at the light receiver unit, and a determination step of determining, from intervals of the at least three flat surfaces detected in the detection step, which one of the front and back surfaces of the wafer is directed upward.

In accordance with a fourth aspect of the present invention, there is provided a front/back surface determination method for determining a front or back surface of a wafer having an outer circumferential chamfered portion, the wafer including a flat surface inclined from a direction orthogonal to the front surface of the wafer and formed in a region of the outer circumferential chamfered portion. The front/back surface determination method includes irradiating a side surface of the outer circumferential chamfered portion, the side surface including the flat surface, with light along a circumferential direction of the wafer by a sensor having a light transmitter unit that irradiates the side surface of the outer circumferential chamfered portion with the light and a light receiver unit that receives reflected light from the side surface, and determining, based on the reflected light from the side surface, which one of the front and back surfaces of the wafer is directed upward.

Preferably, the light to be irradiated from the light transmitter unit may be adjusted so as to have an optical path orthogonal to the flat surface with the one surface of the wafer directed upward, and the light receiver unit may receive the reflected light from the flat surface if the one surface of the wafer is directed upward, but may not receive the reflected light from the flat surface if the other surface of the wafer is directed upward.

Preferably, the sensor may include a first sensor arranged such that the light to be irradiated from the light transmitter unit has an optical path orthogonal to the flat surface with the one surface of the wafer directed upward, and a second sensor arranged such that the light to be irradiated from the light transmitter unit has an optical path orthogonal to the flat surface with the other surface of the wafer directed upward. The front or back surface of the wafer may be determined on the basis of which one of the first sensor and the second sensor has received the reflected light from the flat surface.

In the present invention, these at least three tiny flat surfaces are formed at different intervals along the circumferential direction of the wafer in the region of the outer circumferential chamfered portion of the wafer, or the tiny flat surface is formed, inclined from the direction orthogonal to the front surface of the wafer, in the region of the outer circumferential chamfered portion. Depending on the direction of the wafer, these at least three flat surfaces can be detected in a different order, or the flat surface can or cannot be detected. The front or back surface of the wafer can hence be determined despite the tiny flat surface or these at least three tiny flat surfaces are formed as a mark that indicates a crystal orientation.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view depicting a configuration example of a wafer according to a first embodiment of the first aspect of the present invention;

FIG. 2 is a side view of the wafer of FIG. 1;

FIG. 3 is a top view of the wafer of FIG. 1;

FIG. 4 is a side cross-sectional view depicting a configuration example of a determination system that performs a determination method according to a first embodiment of the third aspect of the present invention;

FIG. 5 is a perspective view depicting the determination system of FIG. 4;

FIG. 6 is a top view illustrating a relation between flat surfaces of the wafer according to the first embodiment of the first aspect and the determination system of FIG. 4 in a case of “front surface up”;

FIG. 7 is a top view illustrating a relation between the flat surfaces of the wafer of FIG. 1 and the determination system of FIG. 4 in a case of “back surface up”;

FIG. 8 is a flow chart illustrating processing procedures of the determination method according to the first embodiment of the third aspect of the present invention;

FIG. 9 is a fragmentary side cross-sectional view depicting a front/back surface determination method according to a first embodiment of the fourth aspect of the present invention for a wafer according to a first embodiment of the second aspect of the present invention in a case of “front surface up”;

FIG. 10 is a fragmentary side cross-sectional view depicting the front/back surface determination method of FIG. 9 for the wafer of FIG. 9 in a case of “back surface up”; and

FIG. 11 is a fragmentary side cross-sectional view depicting a front/back surface determination method according to a second embodiment of the fourth aspect of the present invention for the wafer of FIG. 9 in the case of “front surface up.”

### DETAILED DESCRIPTION OF THE PREFERRED EMBODIMENTS

With reference to the attached drawings, a description will be made in detail about embodiments of the first to fourth aspects of the present invention. However, the present invention shall not be limited by details that will be described in the subsequent embodiments. The elements of configurations that will hereinafter be described include those readily conceivable to persons skilled in the art and substantially the same ones. Further, the configurations that will hereinafter be described can be combined appropriately. Furthermore, various omissions, replacements and modifications of configurations can be made without departing from the spirit of the present invention.

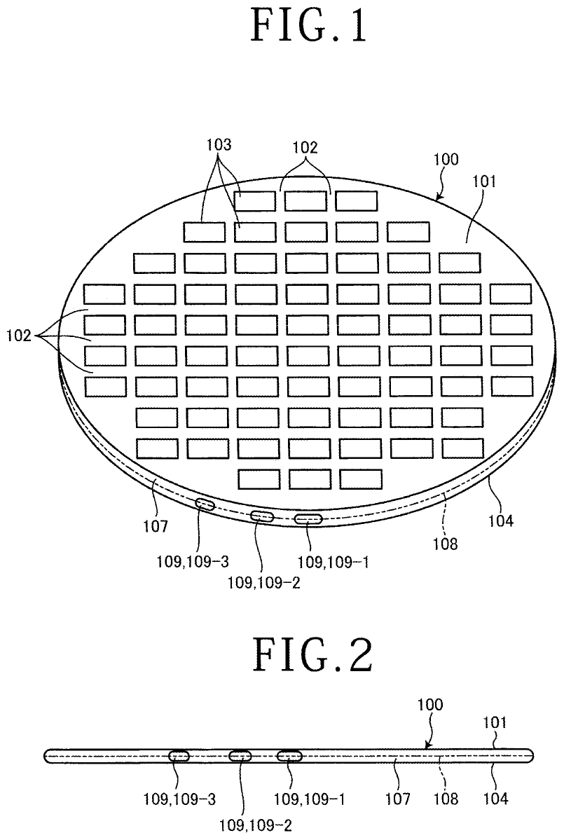

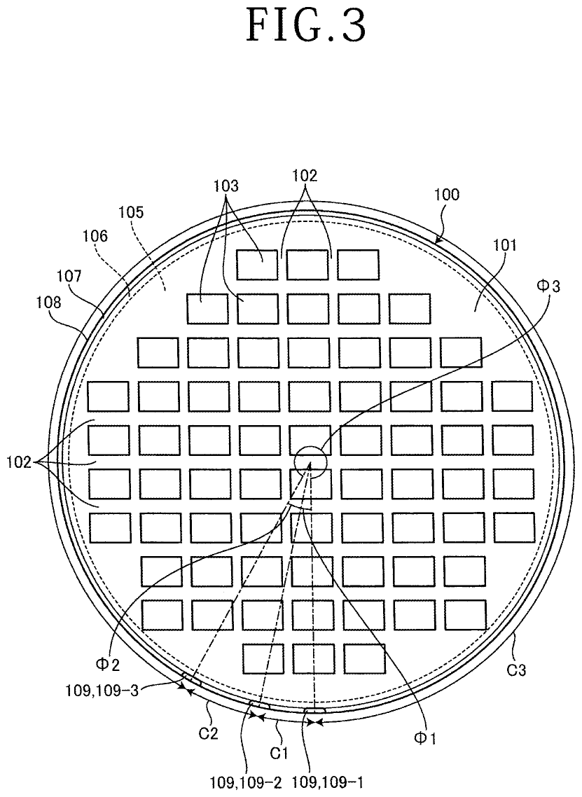

A wafer 100 according to a first embodiment of the first aspect of the present invention and a determination method according to a first embodiment of the third aspect of the present invention will be described on the basis of FIGS. 1 through 7. First, a description will hereinafter be made about the wafer 100 according to the first embodiment. FIG. 1 is a perspective view depicting a configuration example of the wafer 100 according to the first embodiment. FIGS. 2 and 3 are a side view and top view, respectively, of the wafer 100 of FIG. 1. The wafer 100 according to the first embodiment is, as depicted in FIGS. 1, 2, and 3, a disk-shaped semiconductor wafer or optical device wafer, or the like, which uses, for example, silicon, sapphire, silicon carbide (SiC), gallium arsenide, or the like as a substrate. In the wafer 100 of the first embodiment, devices 103 are formed in individual regions defined by intersecting (orthogonal, in the first embodiment) scribe lines 102 on a planar front surface 101. However, the wafer is not limited to the foregoing in the present invention, and the scribe lines 102 and the devices 103 may not be formed on the front surface 101.

As depicted in FIG. 3, the front surface 101 of the wafer 100 can be separated into a device region 105 and an outer circumferential surplus region 106. The device region 105 is a circular region where the devices 103 have been formed or the devices 103 are to be formed. The outer circumferential surplus region 106 is an annular region, which surrounds the device region 105 and where the devices 103 have not been formed or the devices 103 are not to be formed.

As depicted in FIGS. 1, 2, and 3, the wafer 100 is chamfered at an outer circumferential end portion thereof from a side of the front surface 101 to a side of a back surface 104 that is on an opposite side of the front surface 101, whereby an outer circumferential chamfered portion 107 is formed between an outer edge of the front surface 101 and an outer edge of the back surface 104. The front surface 101 and the back surface 104 are formed in a circular shape (for example, in a true circular shape). The outer circumferential chamfered portion 107 has a cross-section, which is orthogonal to the front surface 101 and the back surface 104 and extends along a radial direction of the wafer 100. This cross-section is formed in a substantially semicircular shape symmetrical on sides of the front surface 101 and the back surface 104 with respect to a center plane between the front surface 101 and the back surface 104. At a substantially central portion in a thickness direction of the wafer 100 between the front surface 101 and the back surface 104, the outer circumferential chamfered portion 107 bulges toward an outermost circumferential side in the wafer 100. This substantially central portion forms an outermost circumferential edge 108 of the wafer 100.

As depicted in FIGS. 1, 2, and 3, tiny flat surfaces 109 are formed in a region of the outer circumferential chamfered portion 107 of the wafer 100. In the first embodiment, each flat surface 109 is formed in an elliptical shape, which is orthogonal to the front surface 101 and back surface 104 of the wafer 100 and is also orthogonal to the radial direction of the wafer 100. It is to be noted that each flat surface 109 is not required to be strictly orthogonal to the front surface 101 and back surface 104 of the wafer 100, and may be slightly inclined to a direction orthogonal to the front surface 101 and back surface 104 of the wafer 100. Further, each flat surface 109 is not required to be strictly orthogonal to the radial direction of the wafer 100, and may be slightly inclined to a direction orthogonal to the radial direction of the wafer 100. Owing to the shape of the outer circumferential chamfered portion 107, each flat surface 109 is formed in the elliptical shape that has a major axis parallel to a circumferential direction of the wafer 100.

The word “tiny” as used herein means that each flat surface 109 is formed inward in the radial direction of the wafer 100 from the outermost circumferential edge 108 in a range shorter than a length of the outer circumferential chamfered portion 107 in the radial direction of the wafer 100. Each flat surface 109 is therefore formed on a side of an outer circumference of the wafer 100 beyond the outer edges of the front surface 101 and back surface 104, the outer edges forming opposite ends of the outer circumferential chamfered portion 107. If the wafer 100 has an outer diameter of 200 mm and the length of the outer circumferential chamfered portion 107 in the radial direction of the wafer 100 is 0.5 mm from the outermost circumferential edge 108 of the wafer 100, for example, each flat surface 109 is formed in a range of 0.3 mm on an inner side in the radial direction of the wafer 100 from the outermost circumferential edge 108. With these dimensions, each flat surface 109 has a major diameter of approximately 22 mm. On the other hand, each flat surface 109 has a minor diameter formed shorter than the thickness of the wafer 100. Because each flat surface 109 is formed confined to the outer circumferential chamfered portion 107 as described above, the flat surface 109 is formed with a smaller length compared with an orientation flat which is generally formed in a linear shape along a crystal orientation as seen in plan view. Accordingly, each flat surface 109 is referred to as being “tiny” herein. Because the length of the outer circumferential chamfered portion 107 in the radial direction of the wafer 100 is short and the flat surfaces 109 are tiny, neither the outer circumferential chamfered portion 107 nor the flat surfaces 109 are practically unperceivable to the eye from above. In FIG. 3, however, the outer circumferential chamfered portion 107 and the flat surfaces 109 are exaggerated for emphasis to facilitate understanding of the present invention.

As the flat surfaces 109, at least three (three in the example depicted in FIGS. 1, 2, and 3) flat surfaces 109 are formed along the circumferential direction of the wafer 100 in the first embodiment. The flat surfaces 109 define circular arcs between adjacent ones thereof, respectively. At least two of the circular arcs have lengths different from each other, in other words, the lengths of the three circular arcs are all different from one another. Here, the length of the circular arc between each two adjacent flat surfaces 109 is represented by the length of a fraction of the outermost circumferential edge 108, the fraction being between the centers of each two adjacent flat surfaces 109. In the first embodiment, the length of the circular arc between each two adjacent flat surfaces 109 is also represented, for example, by an angle (hereinafter called “central angle”) formed at the center of the wafer 100 by two straight line segments connecting the centers of these two adjacent flat surfaces 109 with the center of the wafer 100. Here, the central angle has a value greater than 0° and smaller than 360°.

In the first embodiment, at least one (flat surface 109-1) of the three flat surfaces 109 is formed along a crystal orientation. This enables to use this flat surface 109, which is formed along the crystal orientation, as a sign that identifies the crystal orientation (a mark indicating the crystal orientation). The flat surface 109, as described above, can be used as the sign that identifies the crystal orientation, and as will be mentioned subsequently herein, is detected by irradiating it with light and receiving reflected light. The flat surface 109 is therefore also called an orientation mirror (“ORIMIRROR”, Registered Trademark No.4984358 in the name of Disco Corporation).

In the first embodiment, the flat surfaces 109 are formed before the outer circumferential chamfered portion 107 is formed by chamfering processing. Specifically, after formation of the flat surfaces 109 on the outer circumferential end portion of the wafer 100 cut from an ingot, the outer circumferential chamfered portion 107 is formed by chamfering processing. In this manner, chamfering processing can be applied not only to the outer edges of the front surface 101 and back surface 104 of the wafer 100 but also to outer edges of the flat surfaces 109. This can prevent potential occurrence of cracking, chipping, or dusting by an impact that the wafer 100 may receive through inadvertence. Further, at least one flat surface 109 can be suitably formed along the crystal orientation by forming the flat surfaces 109 on the outer circumferential end portion of the wafer 100 cut from the ingot. It is to be noted that, without being limited to the foregoing in the present invention, the flat surfaces 109 may be formed after formation of the outer circumferential chamfered portion 107 by chamfering processing.

As depicted in FIGS. 1, 2, and 3, to distinguish, from one another, the three flat surfaces 109 formed on the wafer 100, they will be referred to as flat surfaces 109-1, 109-2, and 109-3, respectively. As seen from the side of the front surface 101, the flat surface 109-2 is adjacent in a clockwise direction to the flat surface 109-1, the flat surface 109-3 is adjacent in the clockwise direction to the flat surface 109-2, and the flat surface 109-1 is adjacent in the clockwise direction to the flat surface 109-3. As indicated in FIG. 3, the length of the circular arc between the flat surface 109-1 and the flat surface 109-2 is C1 when expressed in terms of the length of a corresponding fraction of the outermost circumferential edge 108, and is φ1 when expressed in central angle. As also indicated in FIG. 3, the length of the circular arc between the flat surface 109-2 and the flat surface 109-3 is C2 when expressed in terms of the length of a corresponding fraction of the outermost circumferential edge 108, and is φ2 when expressed in central angle. As also indicated in FIG. 3, the length of the circular arc between the flat surface 109-3 and the flat surface 109-1 is C3 when expressed in terms of the length of a corresponding fraction of the outermost circumferential edge 108, and is φ3 when expressed in central angle. Here, C1 and C2, C2 and C3, and C3 and C1 are different from each other, respectively, and φ1 and φ2, φ2 and φ3, and φ3 and φ1 are different from each other.

In the wafer 100, the flat surfaces 109-1, 109-2, and 109-3 are formed relatively close to one another in a central angle range of 90° by setting the central angle φ1 and the central angle φ2 to values smaller than 90°, respectively, and setting the central angle φ3 to a value greater than 270° as indicated in FIG. 3, so that the time required for a below-mentioned detection step 1001 can be shortened. It is however to be noted that the wafer 100 is not limited to the foregoing in the present invention and that the flat surfaces 109-1, 109-2, and 109-3 may be formed relatively spaced apart from one another.

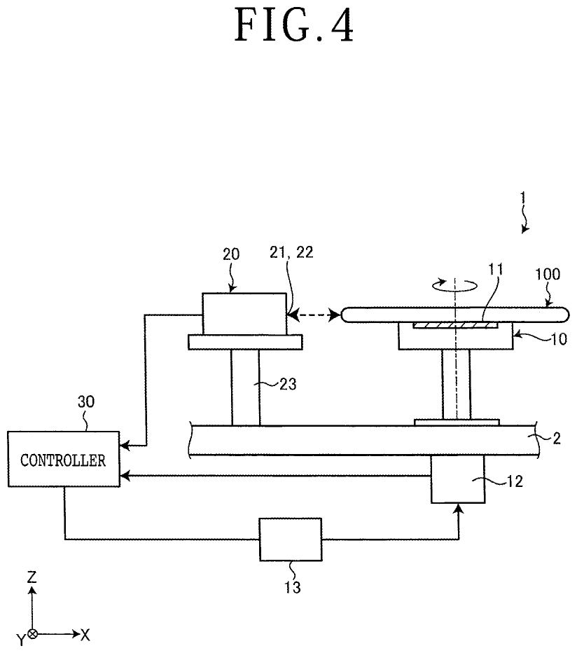

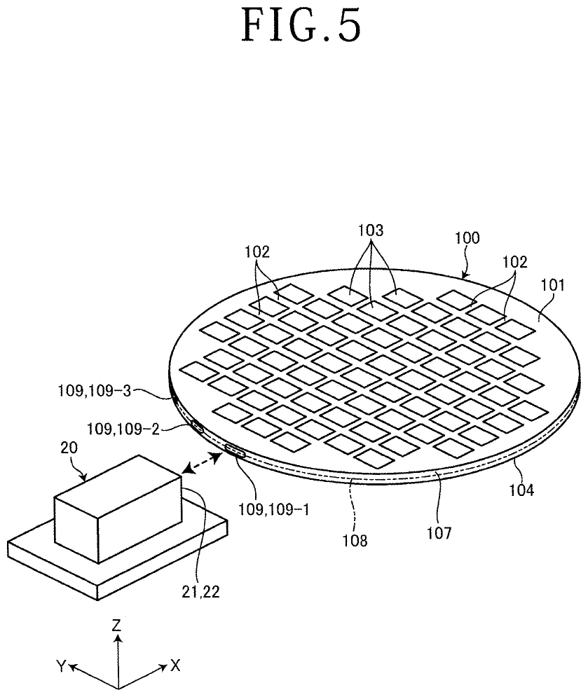

A description will next be made about a determination system 1 that performs the determination method according to the first embodiment of the third aspect of the present invention. FIG. 4 is a side cross-sectional view depicting a configuration example of the determination system 1 that performs the determination method according to the first embodiment. FIG. 5 is a perspective view depicting the determination system 1 of FIG. 4. As depicted in FIG. 4, the determination system 1 includes a holding table 10, a sensor 20, and a controller 30.

As depicted in FIG. 4, the holding table 10 is disposed on a base 2 of the determination system 1, and includes a disk-shaped frame body with a recessed portion formed therein, and a disk-shaped suction portion fitted in the recessed portion. The suction portion of the holding table 10 has a porous portion formed from a porous ceramic or the like that contains a number of pores, and is connected to an undepicted vacuum suction source via an undepicted vacuum suction channel. The suction portion of the holding table 10 functions at an upper surface thereof as a holding surface 11, on which the wafer 100 is placed and is then held under suction, under a negative pressure introduced from the vacuum suction source. In the first embodiment, the holding surface 11 is configured such that the wafer 100 is placed with a predetermined one surface thereof directed upward, and the placed wafer 100 is held under suction from a side of the other surface on the opposite side to the predetermined one surface. The holding surface 11 and a top surface of the frame body of the holding table 10 are arranged on the same plane, and are formed parallel to a horizontal plane (XY plane in FIG. 4).

To a lower side of the holding table 10, the lower side being opposite to the side on which the holding surface 11 is formed, a motor 12 is connected as a rotary drive source so that the holding table 10 is disposed rotatably by the motor 12 about an axis of rotation that is orthogonal to the horizontal plane and is parallel to a vertical direction (Z-axis direction in FIG. 4). The motor 12 is disposed below the holding table 10, and rotates the holding table 10 about the axis of rotation parallel to the vertical direction. The motor 12 is connected with a motor driver 13.

The motor driver 13 supplies driving electric power to the motor 12. The motor driver 13 includes an encoder, which reads rotational positions of the motor 12, and, on the basis of the time variations of the rotational positions of the motor 12 as read by the encoder, detects the rotational speed of the motor 12. The motor driver 13 controls the driving electric power to be supplied to the motor 12, and therefore controls the rotational speed of the motor 12 to be detected. The motor driver 13 is electrically connected with the controller 30 to enable communication of information, is controlled by the controller 30, and outputs the rotational positions and rotational speed of the motor 12 to the controller 30.

Similar to the holding table 10, the sensor 20 is disposed on the base 2 as depicted in FIG. 4. The sensor 20 has a light transmitter unit 21 that emits light in a direction toward the holding table 10, and a light receiver unit 22 that receives the light emitted from the light transmitter unit 21 and reflected from each flat surface 109, that is, reflected light. The light transmitter unit 21 is configured such that the emitted light has an optical path parallel to the horizontal direction, in other words, orthogonal to each flat surface 109. In the first embodiment, the sensor 20 is disposed such that the light transmitter unit 21 and the light receiver unit 22 have the same height in the vertical direction. To a lower side of the sensor 20, a lift unit 23 is connected, so that the sensor 20 is disposed movably by the lift unit 23 along the vertical direction. The lift unit 23 is disposed below the sensor 20, and moves the sensor 20 along the vertical direction, thereby adjusting the light transmitter unit 21 and the light receiver unit 22 so that they oppose a side surface (the outermost circumferential edge 108) of the outer circumferential chamfered portion 107 of the wafer 100 held on the holding table 10 and each flat surface 109, which is formed on the side surface, along the direction of the optical path of the light emitted from the light transmitter unit 21 (the horizontal direction, an X-axis direction in FIG. 4, in the first embodiment).

As depicted in FIG. 5, the sensor 20 is adjusted in height by the lift unit 23 so that the light transmitter unit 21 and light receiver unit 22 and each flat surface 109 of the wafer 100 held on the holding table 10 oppose each other along the direction of the optical path of the light emitted from the light transmitter unit 21, in other words, each flat surface 109 formed on the side surface of the outer circumferential chamfered portion 107 of the wafer 100 is irradiated with the light emitted from the light transmitter unit 21 toward the side surface, the irradiated light is reflected as the reflected light from the flat surface 109, and the reflected light can be received at the light receiver unit 22. After that, the sensor 20 performs a detection operation of each flat surface 109 by emitting the light from the light transmitter unit 21 and receiving the reflected light at the light receiver unit 22. The sensor 20 is electrically connected with the controller 30 to enable communication of information, and outputs, to the controller 30, a signal to the effect that the light receiver unit 22 has received the reflected light from the flat surface 109, in other words, a signal to the effect that the flat surface 109 has been detected.

The controller 30 allows the determination system 1 to perform the determination method according to the first embodiment by controlling operations of individual elements of the determination system 1. The controller 30 controls a suction holding operation of the wafer 100 on the holding surface 11 of the holding table 10, and also controls a rotating operation of the holding table 10 by the motor 12 via the motor driver 13. The controller 30 also controls detection operations of the flat surfaces 109 by the sensor 20, specifically, an emitting operation of light by the light transmitter unit 21 and a receiving operation of reflected light by the light receiver unit 22. The controller 30 also controls the height of the light transmitter unit 21 and light receiver unit 22 along the vertical direction through control of a moving operation of the sensor 20 along the vertical direction by the lift unit 23.

In the controller 30, the lengths C1, C2, and C3 and the central angles φ1, φ2, and φ3, the information on the lengths of the circular arcs between the flat surfaces 109-1, 109-2, and 109-3 formed on the wafer 100, have been recorded and stored beforehand by a worker. In the first embodiment of the third aspect, the controller 30 records and stores the information on the lengths of the circular arcs between the flat surfaces 109, which are formed on the wafer 100, in an order in the clockwise direction as seen from the side of the front surface 101. Without being limited to the foregoing in the present invention, however, the information on the arcs may be recorded and stored in the order in the clockwise direction as seen from the side of the back surface 104, or may be recorded and stored both in the order in the clockwise direction as seen from the side of the front surface 101 and in the clockwise direction as seen from the side of the back surface 104.

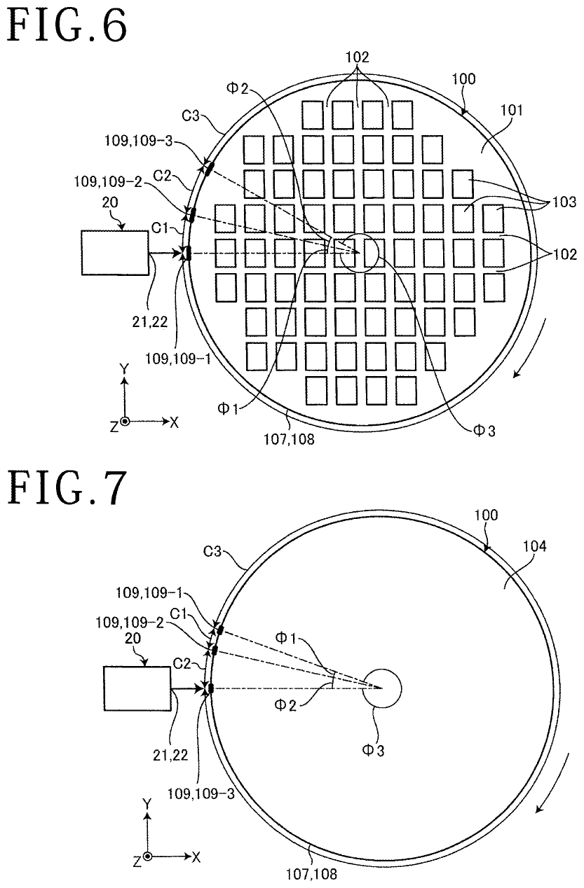

FIGS. 6 and 7 are each a top view illustrating a relation between the flat surfaces 109 of the wafer 100 according to the first embodiment of the first aspect and the determination system 1 in the first embodiment of the third aspect. FIG. 6 is a top view in a case of “front surface up” that the side of the front surface 101 of the wafer 100 held on the holding table 10 is directed upward, and FIG. 7 is a top view in a case of “back surface up” that the side of the back surface 104 of the wafer 100 held on the holding table 10 is directed upward.

If the direction of the wafer 100 held on the holding table 10 is with the front surface 101 up, the controller 30, as depicted in FIG. 6, performs a detection operation of the flat surfaces 109 by the sensor 20 while rotating the holding table 10 in the clockwise direction by the motor 12 as seen from above, whereby the flat surface 109-2 is detected when the holding table 10 is rotated by the central angle φ2 after detection of the flat surface 109-3, the flat surface 109-1 is detected when the holding table 10 is rotated by the central angle φ1 after the detection of the flat surface 109-2, and the flat surface 109-3 is detected when the holding table 10 is rotated by the central angle φ3 after the detection of the flat surface 109-1. In other words, if the direction of the wafer 100 held on the holding table 10 is with the front surface 101 up, the controller 30 performs a detection operation of the flat surfaces 109 while rotating the holding table 10 in the clockwise direction as seen from above, and detects the flat surfaces 109 in the order of the intervals of the central angle φ2, central angle φ1, and central angle φ3. If the direction of the wafer 100 held on the holding table 10 is with the front surface 101 up, the controller 30, as appreciated from the foregoing, detects the flat surfaces 109-1, 109-2, and 109-3 and the lengths C1, C2, and C3 of the circular arcs between the flat surfaces 109-1, 109-2, and 109-3 in an order opposite to that in the direction of rotation of the holding table 10 as seen from above.

If the direction of the wafer 100 held on the holding table 10 is with the back surface 104 up, the controller 30, as depicted in FIG. 7, performs a detection operation of the flat surfaces 109 by the sensor 20 while rotating the holding table 10 in the clockwise direction by the motor 12 as seen from above, whereby the flat surface 109-2 is detected when the holding table 10 is rotated by the central angle φ1 after detection of the flat surface 109-1, the flat surface 109-3 is detected when the holding table 10 is rotated by the central angle φ2 after the detection of the flat surface 109-2, and the flat surface 109-1 is detected when the holding table 10 is rotated by the central angle φ3 after the detection of the flat surface 109-3. In other words, if the direction of the wafer 100 held on the holding table 10 is with the back surface 104 up, the controller 30 performs a detection operation of the flat surfaces 109 while rotating the holding table 10 in the clockwise direction as seen from above, the flat surfaces 109 are detected in the order of the intervals of the central angle φ1, central angle φ2, and central angle φ3. If the direction of the wafer 100 held on the holding table 10 is with the back surface 104 up, the controller 30, as appreciated from the foregoing, detects, when the wafer 100 is seen from the side of the front surface 101, the flat surfaces 109-1, 109-2, and 109-3 and the lengths C1, C2, and C3 of the circular arcs between the flat surfaces 109-1, 109-2, and 109-3 in the same order as that in the direction of rotation of the holding table 10 as seen from above.

If the wafer 100 is seen from the side of the front surface 101, and the flat surfaces 109-1, 109-2, and 109-3 and the lengths C1, C2, and C3 of the circular arcs between the flat surfaces 109-1, 109-2, and 109-3 are detected in the order opposite to that in the direction of rotation of the holding table 10 as seen from above, the controller 30 determines that the direction of the wafer 100 held on the holding table 10 is with the front surface 101 up. If the wafer 100 is seen from the side of the front surface 101, and the flat surfaces 109-1, 109-2, and 109-3 and the lengths C1, C2, and C3 of the circular arcs between the flat surfaces 109-1, 109-2, and 109-3 are detected in the same order as that in the direction of rotation of the holding table 10 as seen from above, the controller 30 determines that the direction of the wafer 100 held on the holding table 10 is with the back surface 104 up. Specifically, if the flat surfaces 109 are detected in the order of the intervals of the central angle φ2, central angle φ1, and central angle φ3 when the detection operation of the flat surfaces 109 is performed by the sensor 20 while rotating the holding table 10 in the clockwise direction as seen from above, the controller 30 determines that the direction of the wafer 100 held on the holding table 10 is with the front surface 101 up. If the flat surfaces 109 are detected in the order of the intervals of the central angle φ1, central angle φ2, and central angle φ3, on the other hand, the controller 30 determines that the direction of the wafer 100 held on the holding table 10 is with the back surface 104 up.

In the first embodiment of the third aspect, the controller 30 includes a computer system. The computer system included in the controller 30 has a processor with a microprocessor such as a central processing unit (CPU), a storage device with a memory such as a read only memory (ROM) or a random access memory (RAM), and an input/output interface device. The processor of the controller 30 performs processing in accordance with a computer program stored in the storage device of the controller 30, and outputs control signals to individual elements of the determination system 1 via the input/output interface device of the controller 30 to control the determination system 1.

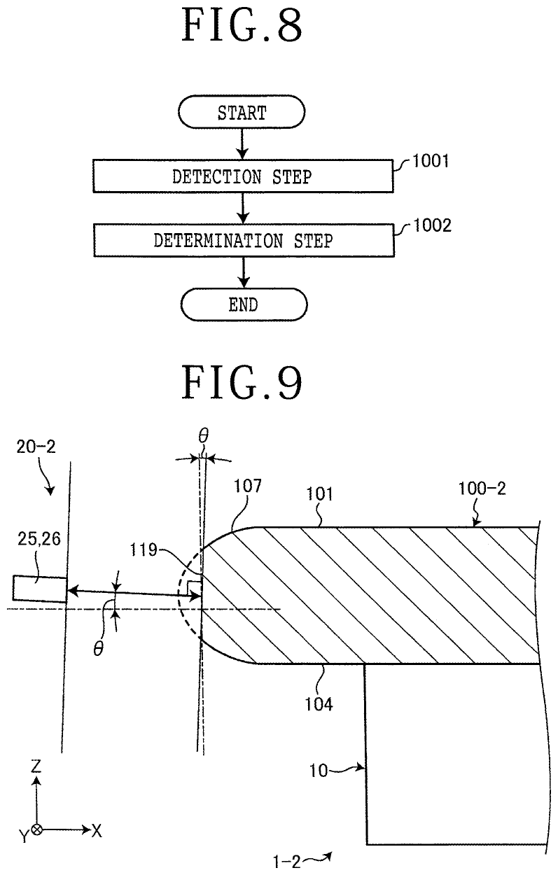

FIG. 8 is a flow chart illustrating processing procedures of the determination method according to the first embodiment of the third aspect. The determination method according to the first embodiment is an example of operation processing to be performed by the determination system 1, and as illustrated in FIG. 8, includes the detection step 1001 and a determination step 1002.

The detection step 1001 irradiates the side surface of the outer circumferential chamfered portion 107 of the wafer 100, the side surface including the flat surfaces 109, with light along the circumferential direction of the wafer 100 by the sensor 20 having the light transmitter unit 21, which irradiates the side surface of the outer circumferential chamfered portion 107 of the wafer 100 with the light, and the light receiver unit 22, which receives reflected light from the side surface, and detects the flat surfaces 109 based on the reflected light received at the light receiver unit 22.

In the detection step 1001, the wafer 100 is first placed on the holding surface 11 of the holding table 10, and is then held under suction on the holding table 10. In the detection step 1001, the controller 30 next adjusts the light transmitter unit 21 and light receiver unit 22 in height by the lift unit 23 so that they oppose each flat surface 109 along the direction of the optical path of the light emitted from the light transmitter unit 21. In the detection step 1001, the controller 30 then performs a detection operation of the flat surfaces 109 by the sensor 20 while rotating the holding table 10 in a predetermined direction (the clockwise direction in the first embodiment) by the motor 12 as seen from above, so that the controller 30 performs a sequential detection operation along the circumferential direction of the wafer 100 to detect the flat surfaces 109 one by one, and the intervals of angular positions of the holding table 10 upon detection of the individual flat surfaces 109 are sequentially detected by the motor driver 13. It is to be noted that, in the detection step 1001, at least two intervals have to be detected, in other words, at least three flat surfaces 109 have to be detected.

The determination step 1002 determines, from these at least two intervals detected in the detection step 1001, which surface of the wafer 100 is directed upward. In the determination step 1002, if the wafer 100 is seen from the side of the front surface 101, and the flat surfaces 109-1, 109-2, and 109-3 and the lengths C1, C2, and C3 of the circular arcs between the flat surfaces 109-1, 109-2, and 109-3 are detected in the order opposite to that in the direction of rotation of the holding table 10 as seen from above, in other words, if the flat surfaces 109 are detected in the order of the intervals of the central angle φ2, central angle φ1, and central angle φ3 as depicted in FIG. 6, the controller 30 determines that the direction of the wafer 100 held on the holding table 10 is with the front surface 101 up. In the determination step 1002, if the wafer 100 is seen from the side of the front surface 101, and the flat surfaces 109-1, 109-2, and 109-3 and the lengths C1, C2, and C3 of the circular arcs between the flat surfaces 109-1, 109-2, and 109-3 are detected in the same order as that in the direction of rotation of the holding table 10 as seen from above, in other words, if the flat surfaces 109 are detected in the order of the intervals of the central angle φ1, central angle φ2, and central angle φ3 as depicted in FIG. 7, on the other hand, the controller 30 determines that the direction of the wafer 100 held on the holding table 10 is with the back surface 104 up.

The wafer 100 according to the first embodiment of the first aspect and the determination method according to the first embodiment of the third aspect, which have configurations as described above, allow to determine the direction of the wafer 100 held on the holding table 10, because the three flat surfaces 109 are formed at the different intervals along the circumference of the wafer 100 in the region of the outer circumferential chamfered portion 107, and the order of detection of the intervals of the flat surfaces 109 is reversed if the direction of the wafer 100 held on the holding table 10 is changed to the opposite. The wafer 100 according to the first embodiment and the determination method according to the first embodiment also allow to keep the outer circumferential surplus region 106 small and to make the device region 105 wide, and hence to make greater the region in which the devices 103 can be formed, because the flat surfaces 109 are tiny. The wafer 100 according to the first embodiment and the determination method according to the first embodiment therefore exhibit an advantageous effect in that the front surface 101 or back surface 104 of the wafer 100 can be determined despite the three tiny flat surface 109 are formed as a mark that indicates a crystal orientation.

After the back surface 104 has been ground and processed to a predetermined thickness, for example, by a grinding machine, the wafer 100 is cut along the scribe lines 102, for example, by a cutting machine, followed by division into the individual devices 103. In particular, a conventional grinding machine is not provided with an imaging unit for performing such an alignment that a positional registration is made between the wafer 100 and a grinding unit that grinds the wafer 100. Therefore, it has heretofore been difficult to determine a front surface 101 or back surface 104 of a wafer 100 even if scribe lines 102 and devices 103 are formed on the front surface 101. It is now possible to determine the front surface 101 or back surface 104 of the wafer 100 by performing the determination method according to the first embodiment with the determination system 1 incorporated in such a grinding machine.

Further, even concerning a wafer 100 a front surface 101 or back surface 104 of which is hardly determined even with use of an imaging unit for performing an alignment because no scribe lines 102 and devices 103 have been formed yet on the front surface 101, the determination method according to the first embodiment can determine the front surface 101 or back surface 104 of the wafer 100.

A wafer 100-2 according to a first embodiment of the second aspect of the present invention and a determination method according to a first embodiment of the fourth aspect of the present invention will next be described on the basis of FIGS. 9 and 10. FIGS. 9 and 10 are each a fragmentary side cross-sectional view depicting a flat surface 119 of the wafer 100-2 according to the first embodiment of the second aspect and the determination method according to the first embodiment of the fourth aspect. The fragmentary side cross-sectional view of FIG. 9 depicts a case of “front surface up” that a side of a front surface 101 of the wafer 100-2 held on the holding table 10 is directed upward, and the fragmentary side cross-sectional view of FIG. 10 depicts a case of “back surface up” that a side of a back surface 104 of the wafer 100-2 held on the holding table 10 is directed upward. It is to be noted that in FIGS. 9 and 10, elements identical to those of the first embodiment of the first aspect and the first embodiment of the third aspect are identified by the same reference signs, and their description is omitted.

As depicted in FIGS. 9 and 10, the wafer 100-2 according to the first embodiment of the second aspect is different from the wafer 100 according to the first embodiment of the first aspect in that, instead of these at least three flat surfaces 109, the at least one flat surface 119 is formed, and the rest of the configuration is similar to that of the wafer 100 according to the first embodiment of the first aspect.

As depicted in FIGS. 9 and 10, the flat surface 119 of the wafer 100-2 according to the first embodiment of the second aspect is formed and slightly inclined by an inclination angle θ from a direction orthogonal to the front surface 101 and back surface 104 of the wafer 100-2 toward an inner side in a radial direction of the wafer 100-2 on the front surface 101 side and toward an outer side in the radial direction of the wafer 100-2 on the back surface 104 side. In the first embodiment of the second aspect, this slight inclination angle θ is, for example, in a range of greater than 0° and equal or smaller than 5° to an extent enabling to detect that the flat surface 119 is inclined, preferably in a range of greater than 0° and equal or smaller than 1° to an extent enabling to detect that the flat surface 119 is inclined. The first embodiment of the second aspect is also different from the first embodiment of the first aspect in that, instead of the three flat surfaces 109, the flat surface 119 is formed and slightly inclined by the inclination angle θ as described above, and the rest of the configuration is similar to that of the flat surfaces 109 in the first embodiment of the first aspect.

A determination system 1-2 that performs the determination method according to the first embodiment of the fourth aspect is different from the determination system 1, which performs the determination method according to the first embodiment of the third aspect, in that, as depicted FIGS. 9 and 10, a sensor 20-2 is included instead of the sensor 20, and the processing at the controller 30 has been changed correspondingly, and the rest of the configuration is similar to that of the determination system 1 that performs the determination method according to the first embodiment of the third aspect.

The sensor 20-2 in the first embodiment of the fourth aspect is different from the sensor 20 in the first embodiment of the third aspect in that the sensor 20-2 has a light transmitter unit 25 and a light receiver unit 26 instead of the light transmitter unit 21 and the light receiver unit 22, and the rest of the configuration is similar to that of the sensor 20 in the first embodiment of the third aspect. As depicted in FIGS. 9 and 10, the light transmitter unit 25 is different from the light transmitter unit 21 in the first embodiment of the third aspect in that the direction of the optical path of the emitted light is inclined downward by an inclination angle θ from the horizontal direction toward the holding table 10, and the rest of the configuration is similar to that of the light transmitter unit 21 in the first embodiment of the third aspect. The light transmitter unit 25 is therefore configured such that the emitted light has an optical path orthogonal to the flat surface 119 of the wafer 100-2 held with the front surface 101 directed upward. The light receiver unit 26 receives the light emitted from the light transmitter unit 25 and reflected from the flat surface 119, that is, reflected light. The sensor 20-2 is disposed such that the light transmitter unit 25 and the light receiver unit 26 have the same height in the vertical direction.

As depicted in FIGS. 9 and 10, the sensor 20-2 is adjusted in height by the lift unit 23 so that the light transmitter unit 25 and light receiver unit 26 and the flat surface 119 of the wafer 100-2 held on the holding table 10 oppose each other along the direction of the optical path of the light emitted from the light transmitter unit 25 (in the first embodiment of the fourth aspect, in a direction inclined downward by the inclination angle θ with respect to the horizontal direction). In other words, the height of the sensor 20-2 is adjusted so that the flat surface 119 formed on the side surface of an outer circumferential chamfered portion 107 of the wafer 100-2 held with the front surface 101 directed upward can be irradiated with light emitted from the light transmitter unit 25 toward the side surface, and the irradiated light can be reflected as reflected light from the flat surface 119, and the reflected light can be received at the light receiver unit 26. After that, the sensor 20-2 performs a detection operation of the flat surface 119 by emitting light from the light transmitter unit 25 and receiving reflected light at the light receiver unit 26.

Assuming now that the direction of the wafer 100-2 held on the holding table 10 is with the front surface 101 up, the detection operation of the flat surface 119 is performed after the height of the sensor 20-2 has been adjusted as described above. The flat surface 119 formed on the side surface of the outer circumferential chamfered portion 107 of the wafer 100-2 is irradiated with light emitted from the light transmitter unit 25 toward the side surface, the light is reflected as reflected light from the flat surface 119, and the light receiver unit 26 detects the reflected light. In this manner, the sensor 20-2 detects the flat surface 119. Assuming next that the direction of the wafer 100-2 held on the holding table 10 is with the back surface 104 up as depicted in FIG. 10, the detection operation of the flat surface 119 is performed after the height of the sensor 20-2 has been adjusted as described above. The flat surface 119 formed on the side surface of the outer circumferential chamfered portion 107 of the wafer 100-2 is irradiated with light emitted from the light transmitter unit 25 toward the side surface, the light is reflected as reflected light from the flat surface 119, and the reflected light is directed downward by twice as much as the inclination angle θ of the light receiver unit 26. Accordingly, the light receiver unit 26 does not receive the reflected light, and the sensor 20-2 does not detect the flat surface 119. As described above, the sensor 20-2 detects or does not detect the flat surface 119 on the basis of whether the light receiver unit 26 receives or does not receive the reflected light from the flat surface 119. This enables to detect whether the direction of the wafer 100-2 held on the holding table 10 is with the front surface 101 up or with the back surface 104 up.

If the sensor 20-2 detects the flat surface 119 on the basis of the reception of reflected light at the light receiver unit 26 from the flat surface 119 when the height of the sensor 20-2 is adjusted by the lift unit 23, and a detection operation of the flat surface 119 is performed by the sensor 20-2 while rotating the holding table 10 in a predetermined direction (for example, the clockwise direction in the first embodiment of the fourth aspect) by the motor 12 as seen from above, the controller 30 determines that the direction of the wafer 100-2 held on the holding table 10 is with the front surface 101 up. If the flat surface 119 is not detected due to lack of reception at the light receiver unit 26 of the reflected light from the flat surface 119, on the other hand, the controller 30 determines that the direction of the wafer 100-2 held on the holding table 10 is with the back surface 104 up.

The determination method according to the first embodiment of the fourth aspect is an example of operation processing to be performed by the determination system 1-2, and is different from the determination method according to the first embodiment of the third aspect in that the detection step 1001 and the determination step 1002 have been both changed.

A detection step 1001 in the first embodiment of the fourth aspect irradiates the side surface of the outer circumferential chamfered portion 107 of the wafer 100-2, the side surface including the flat surface 119, with light along the circumferential direction of the wafer 100-2 by the sensor 20-2 having the light transmitter unit 25, which irradiates the side surface of the outer circumferential chamfered portion 107 of the wafer 100-2 with the light, and the light receiver unit 26, which receives reflected light from the side surface, and detects the flat surface 119 based on the reflected light received at the light receiver unit 26.

The detection step 1001 in the first embodiment of the fourth aspect is different from the detection step 1001 in the first embodiment of the third aspect in that the object to be held under suction on the holding table 10 has been changed to the wafer 100-2, and the controller 30 has been changed to adjust the light transmitter unit 25 and light receiver unit 26 in height by the lift unit 23 so as to bring them into opposition to the flat surface 119 along the optical path of light emitted from the light transmitter unit 25, and the rest of the configuration is similar to that of the detection step 1001 in the first embodiment of the third aspect. In the detection step 1001 in the first embodiment of the fourth aspect, if the direction of the wafer 100-2 held on the holding table 10 is with the front surface 101 up, the light receiver unit 26 receives reflected light from the flat surface 119, and the sensor 20-2 hence detects the flat surface 119. If the direction of the wafer 100-2 held on the holding table 10 is with the back surface 104 up, on the other hand, the sensor 20-2 does not detect the flat surface 119 due to lack of reception at the light receiver unit 26 of reflected light from the flat surface 119.

The determination step 1002 in the first embodiment of the fourth aspect determines, based on the reflected light from the side surface of the outer circumferential chamfered portion 107 of the wafer 100-2, which surface of the wafer 100-2 held on the holding table 10 is directed upward. In the determination step 1002 in the first embodiment of the fourth aspect, if the sensor 20-2 detects the flat surface 119 on the basis of the reception of reflected light at the light receiver unit 26 from the flat surface 119 in the detection step 1001 in the first embodiment of the fourth aspect, the controller 30 determines that the direction of the wafer 100-2 held on the holding table 10 is with the front surface 101 up. If the sensor 20-2 does not detect the flat surface 119 due to lack of reception at the light receiver unit 26 of reflected light from the flat surface 119 in the detection step 1001 in the first embodiment of the fourth aspect, on the other hand, the controller 30 determines that the direction of the wafer 100-2 held on the holding table 10 is with the back surface 104 up.

The wafer 100-2 according to the first embodiment of the second aspect and the determination method according to the first embodiment of the fourth aspect, which have configurations as described above, allow to determine the direction of the wafer 100-2 held on the holding table 10, because the flat surface 119 is formed and slightly inclined from the direction orthogonal to the front surface 101 and back surface 104 of the wafer 100-2, in the region of the outer circumferential chamfered portion 107, and the direction of the reflected light from the flat surface 119 changes on the basis of which surface of the wafer 100-2 is directed upward. The wafer 100-2 according to the first embodiment of the second aspect and the determination method according to the first embodiment of the fourth aspect also allow to keep the outer circumferential surplus region 106 small and to make the device region 105 wide, and hence to make greater the region in which the devices 103 can be formed, because the flat surface 119 is tiny. The wafer 100-2 according to the first embodiment of the second aspect and the determination method according to the first embodiment of the fourth aspect therefore exhibit an advantageous effect in that the front surface 101 or back surface 104 of the wafer 100-2 can be determined despite only the tiny flat surface 119 is formed as a mark that indicates a crystal orientation.

In the first embodiment of the fourth aspect, the front surface 101 or back surface 104 of the wafer 100-2 can be also determined by incorporating the determination system 1-2 in a machine, which is not provided with an imaging unit for performing an alignment, like a grinding machine as in the first embodiment of the third aspect, and performing the determination method according to the first embodiment of the fourth aspect. Further, even concerning a wafer 100-2, a front surface 101 or back surface 104 of which is hardly determined even with use of an imaging unit for performing an alignment because no scribe lines 102 and devices 103 have been formed yet on the front surface 101, the determination method according to the first embodiment of the fourth aspect can determine the front surface 101 or back surface 104 of the wafer 100-2.

In the determination method according to the first embodiment of the fourth aspect, the reflected light from the flat surface 119 is received if the front surface 101 of the wafer 100-2 is directed upward, but the reflected light from the flat surface 119 is not received if the back surface 104 of the wafer 100-2 is directed upward. Without being limited to the foregoing in the present invention, however, the front and back may be reversed. Specifically, the determination method according to the first embodiment of the fourth aspect may be configured such that the reflected light from the flat surface 119 may be received if the back surface 104 of the wafer 100-2 is directed upward, but the reflected light from the flat surface 119 may not be received if the front surface 101 of the wafer 100-2 is directed upward.

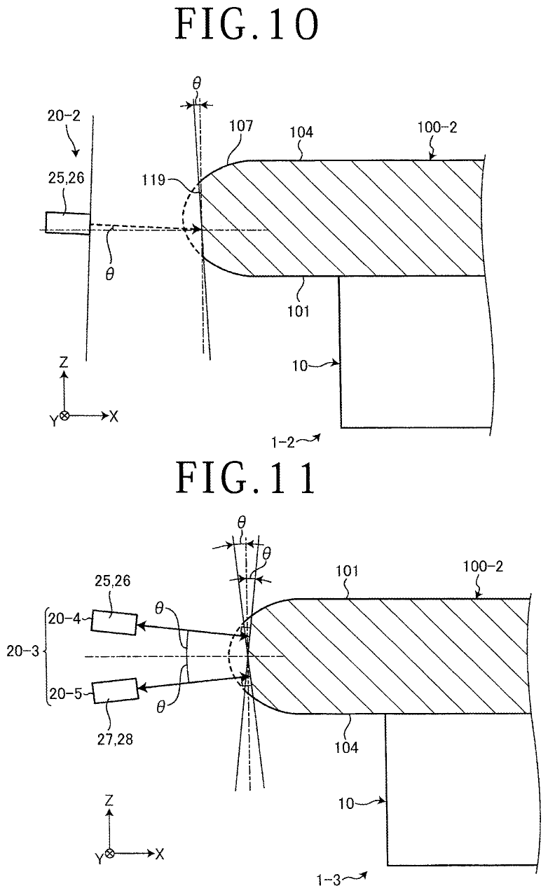

A determination method according to a second embodiment of the fourth aspect will next be described on the basis of FIG. 11. FIG. 11 is a fragmentary side cross-sectional view depicting the determination method according to the second embodiment of the fourth aspect. It is to be noted that, in FIG. 11, elements identical to those of the first embodiment of the fourth aspect are identified by the same reference signs, and their description is omitted.

Similar to the determination method according to the first embodiment of the fourth aspect, the determination method according to the second embodiment of the fourth aspect determines a front surface 101 or back surface 104 of a wafer 100-2. A determination system 1-3 that performs the determination method according to the second embodiment of the fourth aspect is different from the determination system 1-2, which performs the determination method according to the first embodiment of the fourth aspect, in that as depicted FIG. 11, a sensor 20-3 is included instead of the sensor 20-2, and the processing at the controller 30 has been changed correspondingly, and the rest of the configuration is similar to that of the determination system 1-2 that performs the determination method according to the first embodiment of the fourth aspect.

The sensor 20-3 is configured including a first sensor 20-4 and a second sensor 20-5. The first sensor 20-4 has a similar configuration as the sensor 20-2 in the first embodiment of the fourth aspect, in other words, has a similar light transmitter unit 25 and light receiver unit 26 as in the first embodiment of the fourth aspect. The second sensor 20-5 has a light transmitter unit 27 and a light receiver unit 28. As depicted in FIG. 11, the light transmitter unit 27 is different from the light transmitter unit 21 in the first embodiment of the third aspect in that the direction of the optical path of emitted light is inclined upward by an inclination angle θ from the horizontal direction toward the holding table 10, and the rest of the configuration is similar to that of the light transmitter unit 21 in the first embodiment of the third aspect. The light transmitter unit 27 is therefore configured such that the emitted light has an optical path orthogonal to the flat surface 119 of the wafer 100-2 held with the back surface 104 directed upward. The light receiver unit 28 receives the light emitted from the light transmitter unit 27 and reflected from the flat surface 119, that is, reflected light. The second sensor 20-5 is disposed such that the light transmitter unit 27 and the light receiver unit 28 have the same height in the vertical direction.

The first sensor 20-4 is disposed above the second sensor 20-5. The first sensor 20-4 and the second sensor 20-5 are arranged symmetrically with respect to a predetermined horizontal plane in the vertical direction. The first sensor 20-4 and the second sensor 20-5 are arranged spaced apart from each other by a predetermined distance in the vertical direction so that, when the first sensor 20-4 is positioned at a height where the first sensor 20-4 can detect the flat surface 119 of the wafer 100-2 held with the front surface 101 directed upward, the second sensor 20-5 is positioned at a height where the second sensor 20-5 can detect the flat surface 119 of the wafer 100-2 held with the back surface 104 directed upward.

As depicted in FIG. 11, the sensor 20-3 is adjusted in height by the lift unit 23 so that the light transmitter unit 25 and light receiver unit 26 and the flat surface 119 of the wafer 100-2 held on the holding table 10 oppose each other along the direction of the optical path of the light emitted from the light transmitter unit 25, and the light transmitter unit 27 and light receiver unit 28 and the flat surface 119 of the wafer 100-2 held on the holding table 10 oppose each other along the direction of the optical path of the light emitted from the light transmitter unit 25 (in a direction inclined upward by an inclination angle θ with respect to the horizontal direction toward the holding table 10). In other words, the height of the sensor 20-3 is adjusted so that the flat surface 119 formed on the side surface of the outer circumferential chamfered portion 107 of the wafer 100-2 held with the front surface 101 directed upward can be irradiated with light emitted from the light transmitter unit 25 toward the side surface, the irradiated light can be reflected as reflected light from the flat surface 119, and the reflected light can be received at the light receiver unit 26, and, in addition, the flat surface 119 formed on the side surface of the outer circumferential chamfered portion 107 of the wafer 100-2 held with the back surface 104 directed upward can be irradiated with light emitted from the light transmitter unit 27 toward the side surface, the irradiated light can be reflected as reflected light from the flat surface 119, and the reflected light can be received at the light receiver unit 28. After that, the sensor 20-3 performs a detection operation of the flat surface 119 by emitting light from the light transmitter units 25 and 27 and receiving reflected light at the light receiver unit 26 and 28.

Assuming now that the direction of the wafer 100-2 held on the holding table 10 is with the front surface 101 up as depicted in FIG. 11, the detection operation of the flat surface 119 is performed after the height of the sensor 20-3 has been adjusted as described above. The flat surface 119 formed on the side surface of the outer circumferential chamfered portion 107 of the wafer 100-2 is irradiated with light emitted from the light transmitter unit 25 toward the side surface, the irradiated light is reflected as reflected light from the flat surface 119, and the reflected light is received at the light receiver unit 26. In this manner, the first sensor 20-4 detects the flat surface 119. Assuming next that the direction of the wafer 100-2 held on the holding table 10 is with the back surface 104 up, on the other hand, the detection operation of the flat surface 119 is performed after the height of the sensor 20-3 has been adjusted as described above. The flat surface 119 formed on the side surface of the outer circumferential chamfered portion 107 of the wafer 100-2 is irradiated with light emitted from the light transmitter unit 27 toward the side surface, the irradiated light is reflected as reflected light from the flat surface 119, and the light receiver unit 28 receives the reflected light. In this manner, the second sensor 20-5 detects the flat surface 119. On the basis of which one of the light receiver units 26 and 28 of the first sensor 20-4 and second sensor 20-5 receives the reflected light from the flat surface 119, in other words, on the basis of which one of the first sensor 20-4 and the second sensor 20-5 detects the flat surface 119, the sensor 20-3 can detect whether the direction of the wafer 100-2 held on the holding table 10 is with the front surface 101 up or with the back surface 104 up.

If the first sensor 20-4 detects the flat surface 119 on the basis of the detection of reflected light at the light receiver unit 26 from the flat surface 119 when the height of the sensor 20-3 is adjusted by the lift unit 23, and a detection operation of the flat surface 119 is performed by the sensor 20-3 while rotating the holding table 10 in a predetermined direction (for example, the clockwise direction in the second embodiment of the fourth aspect) by the motor 12 as seen from above, the controller 30 determines that the direction of the wafer 100-2 held on the holding table 10 is with the front surface 101 up. If the second sensor 20-5 detects the flat surface 119 on the basis of the detection of reflected light at the light receiver unit 28 from the flat surface 119, on the other hand, the controller 30 determines that the direction of the wafer 100-2 held on the holding table 10 is with the back surface 104 up.

The determination method according to the second embodiment of the fourth aspect is an example of operation processing to be performed by the determination system 1-3, and is different from the determination method according to the first embodiment of the fourth aspect in that the detection step 1001 and the determination step 1002 have been both changed.

The detection step 1001 in the second embodiment of the fourth aspect is different from the detection step 1001 in the first embodiment of the fourth aspect in that the flat surface 119 is detected by the sensor 20-3 instead of the sensor 20-2, specifically the flat surface 119 is detected by also using the second sensor 20-5 in addition to the first sensor 20-4 which is substantially similar to the sensor 20-2, and the rest of the configuration is similar to that of the detection step 1001 in the first embodiment of the fourth aspect. In the detection step 1001 in the second embodiment of the fourth aspect, if the direction of the wafer 100-2 held on the holding table 10 is with the front surface 101 up, the first sensor 20-4 detects the flat surface 119 on the basis of the reception of reflected light at the light receiver unit 26 from the flat surface 119. If the direction of the wafer 100-2 held on the holding table 10 is with the back surface 104 up, on the other hand, the second sensor 20-5 detects the flat surface 119 on the basis of the reception of reflected light at the light receiver unit 28 from the flat surface 119.

The determination step 1002 in the second embodiment of the fourth aspect determines the direction of the wafer 100-2 on the basis of which one of the first sensor 20-4 and the second sensor 20-5 has received the reflected light from the flat surface 119. In the determination step 1002 in the second embodiment of the fourth aspect, if the first sensor 20-4 detects the flat surface 119 on the basis of the reception of reflected light at the light receiver unit 26 from the flat surface 119 in the detection step 1001 in the second embodiment of the fourth aspect, the controller 30 determines that the direction of the wafer 100-2 held on the holding table 10 is with the front surface 101 up. If the second sensor 20-5 detects the flat surface 119 on the basis of the reception of reflected light at the light receiver unit 28 from the flat surface 119 in the detection step 1001 in the second embodiment of the fourth aspect, on the other hand, the controller 30 determines that the direction of the wafer 100-2 held on the holding table 10 is with the back surface 104 up.

The determination method according to the second embodiment of the fourth aspect, which has a configuration as described above, allows, as in the first embodiment of the fourth aspect, to determine the direction of the wafer 100-2 held on the holding table 10, because the flat surface 119 is formed and slightly inclined from the direction orthogonal to the front surface 101 and back surface 104 of the wafer 100-2, in the region of the outer circumferential chamfered portion 107, and the direction of the reflected light from the flat surface 119 changes on the basis of which surface of the wafer 100-2 is directed upward. The determination method according to the second embodiment of the fourth aspect also allows, as in the first embodiment of the fourth aspect, to keep the outer circumferential surplus region 106 small and to make the device region 105 wide, and hence to make greater the region in which the devices 103 can be formed, because the flat surface 119 is tiny. The determination method according to the second embodiment of the fourth aspect therefore exhibits an advantageous effect in that the front surface 101 or back surface 104 of the wafer 100-2 can be determined despite only the tiny flat surface 119 is formed as a mark that indicates a crystal orientation.

In the second embodiment of the fourth aspect, the front surface 101 or back surface 104 of the wafer 100-2 can be also determined by incorporating the determination system 1-3 in a machine, which is not provided with an imaging unit for performing an alignment, like a grinding machine as in the first embodiment of the third aspect and the first embodiment of the fourth aspect, and performing the determination method according to the second embodiment of the fourth aspect. Further, even concerning a wafer 100-2 a front surface 101 or back surface 104 of which is hardly determined even with use of an imaging unit for performing an alignment because no scribe lines 102 and devices 103 have been formed yet on the front surface 101, the determination method according to the second embodiment of the fourth aspect can determine the front surface 101 or back surface 104 of the wafer 100-2.

The present invention is not limited to the details of the above-described preferred embodiments. The scope of the invention is defined by the appended claims and all changes and modifications as fall within the equivalence of the scope of the claims are therefore to be embraced by the invention.

What is claimed is:

1. A wafer having an outer circumferential chamfered portion, comprising:
at least three tiny flat surfaces formed along a circumferential direction of the wafer in a region of the outer circumferential chamfered portion, wherein
the flat surfaces define circular arcs between adjacent ones thereof, respectively, and at least two of the circular arcs have lengths different from each other.

2. A wafer having an outer circumferential chamfered portion, comprising:
a flat surface inclined from a direction orthogonal to a front surface of the wafer and formed in a region of the outer circumferential chamfered portion.

3. A front/back surface determination method for determining a front or back surface of a wafer having an outer circumferential chamfered portion and including at least three tiny flat surfaces formed along a circumferential direction of the wafer in a region of the outer circumferential chamfered portion, the flat surfaces defining circular arcs between adjacent ones thereof, respectively, and at least two of the circular arcs having lengths different from each other, comprising:
a detection step of irradiating a side surface of the outer circumferential chamfered portion, the side surface including the flat surfaces, with light along the circumferential direction of the wafer by a sensor having a light transmitter unit that irradiates the side surface of the outer circumferential chamfered portion with the light and a light receiver unit that receives reflected light from the side surface, thereby detecting a plurality of the flat surfaces based on the reflected light received at the light receiver unit, and
a determination step of determining, from intervals of the at least three flat surfaces detected in the detection step, which one of the front and back surfaces of the wafer is directed upward.

4. A front/back surface determination method for determining a front or back surface of a wafer having an outer circumferential chamfered portion, the wafer including a flat surface inclined from a direction orthogonal to the front surface of the wafer and formed in a region of the outer circumferential chamfered portion, comprising:
irradiating a side surface of the outer circumferential chamfered portion, the side surface including the flat surface, with light along a circumferential direction of the wafer by a sensor having a light transmitter unit that irradiates the side surface of the outer circumferential chamfered portion with the light and a light receiver unit that receives reflected light from the side surface, and determining, based on the reflected light from the side surface, which one of the front and back surfaces of the wafer is directed upward.

5. The front/back surface determination method according to claim 4, wherein
the light to be irradiated from the light transmitter unit is adjusted so as to have an optical path orthogonal to the flat surface with the one surface of the wafer directed upward, and
the light receiver unit receives the reflected light from the flat surface if the one surface of the wafer is directed upward, but does not receive the reflected light from the flat surface if the other surface of the wafer is directed upward.

6. The front/back surface determination method according to claim 4, wherein
the sensor includes
a first sensor arranged such that the light to be irradiated from the light transmitter unit has an optical path orthogonal to the flat surface with the one surface of the wafer directed upward, and
a second sensor arranged such that the light to be irradiated from the light transmitter unit has an optical path orthogonal to the flat surface with the other surface of the wafer directed upward, and
the front or back surface of the wafer is determined on a basis of which one of the first sensor and the second sensor has received the reflected light from the flat surface.
